(19) United States
(12) Patent Application Publication
(10) Pub. No.: US 2024/0431026 A1
(43) Pub. Date: Dec. 26, 2024

(54) APPARATUSES HAVING VIA STRUCTURES TO REDUCE CROSSTALK EFFECTS

(71) Applicant: Samsung Electronics Co., Ltd., Suwon-si (KR)

(72) Inventors: Jaeho CHOI, Suwon-si (KR); Jonghoon KIM, Suwon-si (KR); Dongyoon SEO, Suwon-si (KR); Dohyung KIM, Suwon-si (KR); Wonseop LEE, Suwon-si (KR); Daae HUH, Suwon-si (KR)

(73) Assignee: Samsung Electronics Co., Ltd., Suwon-si (KR)

(21) Appl. No.: 18/749,099

(22) Filed: Jun. 20, 2024

(30) Foreign Application Priority Data
Jun. 22, 2023 (KR) 10-2023-0080638

(51) Int. Cl. H05K 1/11; H05K 1/18

(52) U.S. Cl. CPC H05K 1/115; H05K 1/181; H05K 2201/09509; H05K 2201/09609; H05K 2201/10159

(57) ABSTRACT

An apparatus including via structures capable of reducing crosstalk effects is provided. The apparatus includes a printed circuit board (PCB) including sequentially stacked multi-layers, a first via structure that partially penetrates the multilayers of the PCB and is connected to a first metal plate on a first layer of the multilayers, and a second via structure adjacent to the first via structure in a horizontal direction, partially penetrating the multi-layers of the PCB, and connected to a second metal plate disposed on a second layer of the multi-layers. A portion where the first metal plate and the second metal plate overlap each other is configured to provide a first mutual capacitive coupling between the first and second via structures.

### CROSS-REFERENCE TO RELATED APPLICATION

This application is based on and claims priority under 35 U.S.C. § 119 to Korean Patent Application No. 10-2023-0080638, filed on Jun. 22, 2023, in the Korean Intellectual Property Office, the disclosure of which is incorporated by reference herein in its entirety.

### BACKGROUND

Various example embodiments relate to apparatuses, and more particularly, to apparatuses capable of reducing crosstalk effects.

Crosstalk may be defined as inductive coupling between adjacent vias. Far end crosstalk (FEXT) is a crosstalk and/or interference between two signal pairs on an interconnect or bus and is measured at an opposite end of a signal line from an interfering transmitter. Single ended interconnects and/or buses may be used to connect a memory device to a printed circuit board (PCB) or package. Adjacent buses of a memory device may experience FEXT effects from adjacent signals. FEXT is a key limiting factor in high-speed signaling because the FEXT acts as a detrimental noise source on a bus and distorts a signal. Reducing the FEXT effect may be beneficial for high-speed and/or high-performance operation of memory devices.

### SUMMARY

Various example embodiments may provide apparatuses having via structures capable of reducing crosstalk effects.

According to various example embodiments, there is provided an apparatus including a printed circuit board (PCB) including sequentially stacked multi-layers, a first via structure that partially penetrates the multi-layers of the PCB and is connected to a first metal plate disposed on a first layer of the multi-layers, and a second via structure adjacent to the first via structure in a horizontal direction, partially penetrating the multi-layers of the PCB, and connected to a second metal plate on a second layer of the multi-layers. A portion where the first metal plate and the second metal plate overlap each other and is configured to have a first mutual capacitive coupling between the first and second via structures.

Alternatively or additionally according to various example embodiments, there is provided an apparatus including a printed circuit board (PCB) including sequentially stacked N (N is a natural number) layers, and N number of via structures respectively configured to transmit N number of signals and passing through each of the N number of layers of the PCB, wherein a first mutual capacitive coupling is configured to be between first and second via structures adjacent to each other in a horizontal direction of the PCB among the N number of via structures, and a second mutual capacitive coupling is configured to be between third and fourth via structures overlapping each of the first and second via structures in a vertical direction among the N via structures.

Alternatively or additionally according to various example embodiments, there is provided a via structure including a barrel on a printed circuit board (PCB) including sequentially stacked multi-layers, and a conductive material film having an insulating material film embedded in the center of the barrel, wherein the barrel provides a signal entry point and a signal exit point and partially penetrates the multi-layers, and a layer on which a metal plate is arranged from among the penetrated layers between the signal entry point and the signal exit point is configured to provide a mutual capacitance point, and the conductive material film in a region of the signal entry and exit points is arranged to have a size greater than the conductive material film in a region of the mutual capacitance point.

### BRIEF DESCRIPTION OF THE DRAWINGS

Various example embodiments will be more clearly understood from the following detailed description taken in conjunction with the accompanying drawings in which:

FIG. 1 is a diagram illustrating an apparatus having a via structure according to some example embodiments;

FIG. 2 is a cross-sectional view taken along line X-X′ of a memory module of FIG. 1;

FIGS. 3A to 3C are diagrams illustrating via structures of FIG. 2;

FIGS. 4A to 6C are diagrams illustrating capacitance patterns included in via structures according to some example embodiments;

FIG. 7 is a diagram illustrating mutual capacitances of via structures according to some example embodiments;

FIG. 8 is a diagram illustrating a via structure according to some example embodiments;

FIG. 9 is a diagram illustrating a via structure according to some example embodiments;

FIGS. 10 to 12 are diagrams illustrating memory modules according to some example embodiments; and

FIG. 13 is a block diagram of a system for describing an electronic device including memory modules according to some example embodiments.

### DETAILED DESCRIPTION OF VARIOUS EXAMPLE EMBODIMENTS

Example embodiments relate, in general, to via structures to reduce crosstalk, particularly far end crosstalk (FEXT) of high-speed single-ended buses. In signaling, FEXT is proportional to an amount of capacitance and inductance [Cm/Cs-Lm/Ls]. Cm, Cs, Lm, and Ls denote mutual capacitance, self-capacitance, mutual inductance, and self-inductance, respectively. Because the Lm/Ls term proportional to the signal line length has a large value, FEXT may be reduced by increasing the Cm term. Example embodiments include via structures that reduce inductive coupling that occurs between adjacent vias in bus and/or in interconnect technologies using metal plates added to vias. The metal plates generate capacitive coupling that may compensate for an inductive crosstalk typically created between vias in a printed circuit board (PCB) or package. When metal plates added to two adjacent vias overlap each other, a capacitive coupling is or may be created, resulting in increasing a mutual capacitance and improving overall performance. Hereinafter, in order to increase mutual capacitance to make a balance with the inductive coupling, via structures forming mutual capacitive coupling using a capacitance pattern are provided.

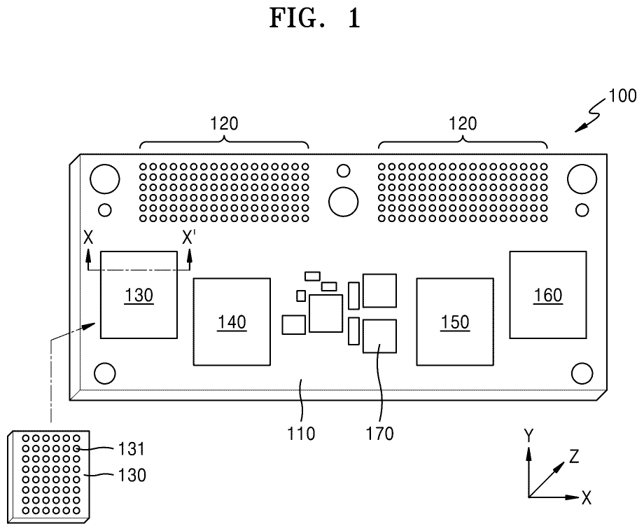

FIG. 1 is a diagram illustrating an apparatus 100 having a via structure according to some example embodiments. The apparatus 100 of FIG. 1 is an example implemented as a memory module; however, example embodiments are not limited thereto. For convenience of description, the apparatus 100 is described as a memory module, and the same applies in the following embodiments. The term apparatus 100 and the term memory module 100 may be used interchangeably.

Referring to FIG. 1, the memory module 100 may include a module substrate 110, a module connector 120, and memory packages 130, 140, 150, and 160. In addition, the memory module 100 may further include passive elements 170 disposed on the module substrate 110.

The module substrate 110 may be or may include or be included in a multilayer circuit board having a first surface (or upper surface) and a second surface (or lower surface) facing each other. For example, the module substrate 110 may be or include or be included in a PCB including multiple layers sequentially stacked. As described below, the PCB may include wires formed on a surface and/or on the inside, along with vias for connecting the wires. The wires may be a conductive pattern such as a printed circuit pattern for interconnecting the module connector 120, the memory packages 130, 140, 150, and 160, and the passive elements 170.

The module connector 120 may be disposed on the module substrate 110 to be connected to a system board on which the memory module 100 is mounted. The module connector 120 may include a conductive material. The module connector 120 may be disposed on the first surface of the module substrate 110 to which the memory packages 130, 140, 150, and 160 are attached. Although not shown in FIG. 1, the module connector 120 may also be disposed on the second surface opposite to the first surface of the module substrate 110.

The memory packages 130, 140, 150, and 160 are volatile memory devices such as one or more of dynamic random access memory (DRAM), static random access memory (SRAM), mobile DRAM, double data rate synchronous dynamic random access memory (DDR SDRAM), low power DDR (LPDDR) SDRAM, graphic DDR (GDDR), SDRAM, Rambus dynamic random access memory (RDRAM), and the like. Alternatively or additionally, the memory packages 130, 140, 150, and 160 are non-volatile memory devices such as one or more of electrically erasable programmable read-only memory (EEPROM), flash memory, phase change random access memory (PRAM), resistance random access memory (RRAM), nano floating gate memory (NFGM), polymer random access memory (PoRAM), magnetic random-access memory (MRAM), ferroelectric random access memory (FRAM), and the like.

The memory packages 130, 140, 150, and 160 each include a package of a ball grid array (BGA) type and may be disposed on the first surface of the module substrate 110. For example, the memory package 130 may be disposed on the first surface of the module substrate 110 facing pins 131 of a solder ball type of the memory package 130. The passive elements 170 are disposed on the first surface of the module substrate 110 and may include inductors, capacitors, resistors, memristors, and the like. For convenience of description, the memory packages 130, 140, 150, and 160 are described as including DDR DRAM, but the technical ideas of inventive concepts are not limited thereto. In some example embodiments, the memory module 100 is described as a compression-attached memory module (CAMM), and is equally applied in the following embodiments. The CAMMs may be used in mobile computing environments with limited capacity for heat dissipation and/or standard office environments for desktop and all-in-one (AIO) systems with heating and/or air conditioning apparatuses.

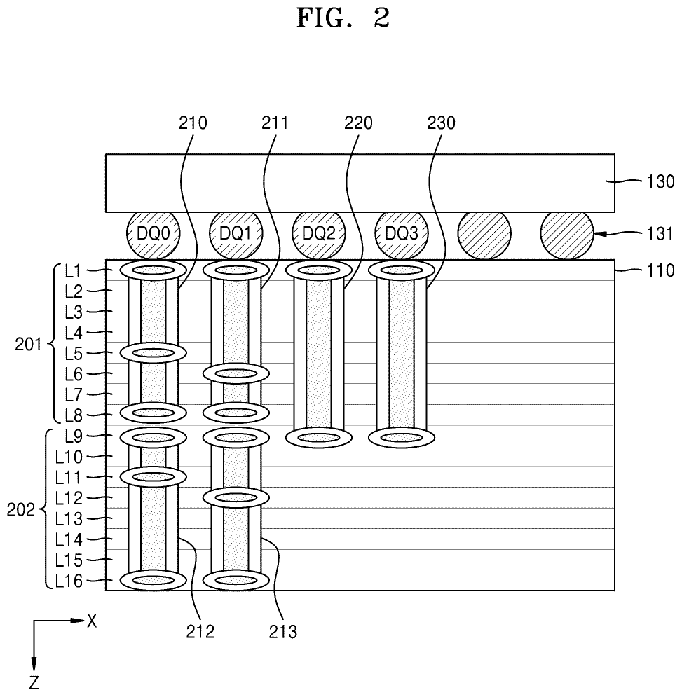

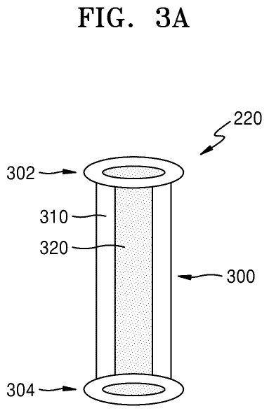

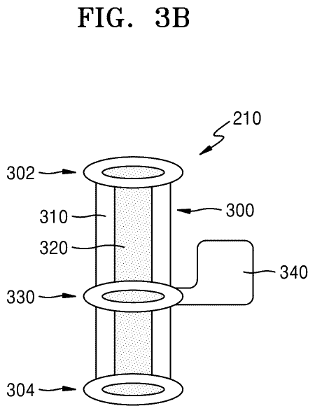

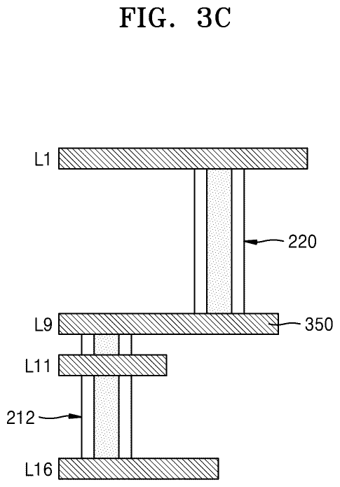

FIGS. 2 to 3C are diagrams illustrating the module substrate 110 having a via structure according to some example embodiments. FIG. 2 is a cross-sectional view taken along line X-X′ of the memory module 100 of FIG. 1. FIGS. 3A to 3C are diagrams illustrating the via structures of FIG. 2. For convenience of description, the term module substrate 110 and the term PCB 110 may be used interchangeably.

Referring to FIGS. 1 and 2, the module substrate 110 may be a multilayer PCB. The PCB 110 may include first to sixteenth layers L1 to L16. The first to sixteenth layers L1 to L16 may be divided into upper layers 201 and lower layers 202, and the first to eighth layers L1 to L8 are included in the upper layers 201, and the 9th to 16th layers L9 to L16 may be included in the lower layers 202. The first to sixteenth layers L1 to L16 include a plurality of via structures 210, 211, 212, 213, 220, and 230, and the plurality of via structures 210, 211, 212, and 213, 220, and 230 may be connected to wires formed inside the first to sixteenth layers L1 to L16. The plurality of via structures 210, 211, 212, 213, 220, and 230 may be signal vias and may be arranged at certain intervals from each other.

The pins 131 of the memory package 130 may contact the first layer L1 which is the uppermost layer of the PCB 110. For example, the pins 131 of the memory package 130 may be data signal pins DQ0, DQ1, DQ2, and DQ3, respectively. According to various example embodiment, the pins 131 of the memory package 130 may be pins of clock, command/address, and control signals. Each of the data signals DQ0, DQ1, DQ2, and DQ3 of the memory package 130 may be connected to each of the via structures 210, 211, 212, 213, 220, and 230 formed on the PCB 110.

Referring to FIGS. 3A and 3B, among the via structures 210, 211, 212, 213, 220, and 230 of FIG. 2, the via structures 220 and 210 having different shapes are shown. The via structures 220 and 210 may include a barrel 300 and a signal entry point (e.g., 302) and a signal exit point (e.g., 304) within the PCB 110. In the barrel 300, a conductive material film 310 having an insulating material film 320 is formed at the center of the barrel 300, e.g., is formed coaxially. The barrel 300 may include a blind via hole (BVH) barrel or a buried via hole (BVH) barrel that are configured to connect the signal entry and exit points 302 and 304 to other layers. The conductive material film 310 between the signal entry point 302 and the signal exit point 304 may provide a signal line. A metal plate for increasing mutual capacitance may be formed on the signal line between the signal entry point 302 and the signal exit point 304. As shown in FIG. 3B, the via structure 210 includes a mutual capacitance point 330 between the signal entry point 302 and the signal exit point 304, and a signal line of the mutual capacitance point 330 may be connected to a plate 340.

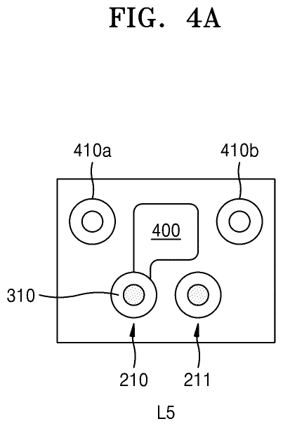

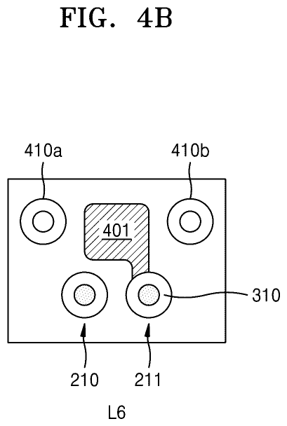

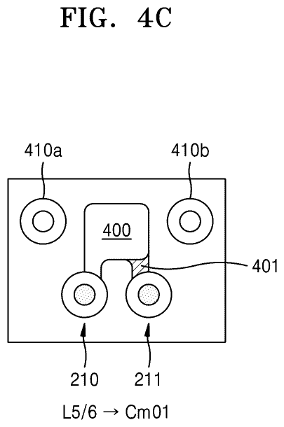

Referring to FIG. 2 in connection with FIGS. 3A and 3B, the DQ0 data signal of the memory package 130 may be connected to the via structure 210 and the DQ1 data signal may be connected to the via structure 211. The via structures 210 and 211 may be disposed adjacent to each other in an X-axis direction (e.g., in a horizontal axis direction). The via structures 210 and 211 are formed on the upper layers 201 of the PCB 110, the signal entry point 302 is formed on the first layer L1, and the signal exit point 304 is formed on the eighth layer L8. The mutual capacitance point 330 of the via structure 210 is formed on the fifth layer L5 and may be correlated with or associated with a plate 340 formed on the fifth layer L5 (e.g., FIG. 4A). The mutual capacitance point 330 of the via structure 211 is formed on the sixth layer L6 and may be correlated with the plate 340 formed on the sixth layer L6 (e.g., FIG. 4B). The plate 340 of the fifth layer L5 and the plate 340 of the sixth layer L6 may have an overlapping region with each other (e.g., FIG. 4C), and a capacitive coupling may be generated between the plates overlapping each other to increase a mutual capacitance.

The DQ2 data signal may be connected to the via structure 220 and the DQ3 data signal may be connected to the via structure 230. In the via structures 220 and 230, a signal entry point 302 is formed on the first layer L1 of the PCB 110 and a signal exit point 304 is formed on the ninth layer L9. Each of the via structures 220 and 230 may be connected to the via structures 212 and 213 in the ninth layer L9. As an example, as shown in FIG. 3C, the via structure 220 may be connected to the via structure 212 through a wiring 350 formed in the ninth layer L9. Similarly, the via structure 230 may also be connected to the via structure 213 through the wiring 350 formed in the ninth layer L9.

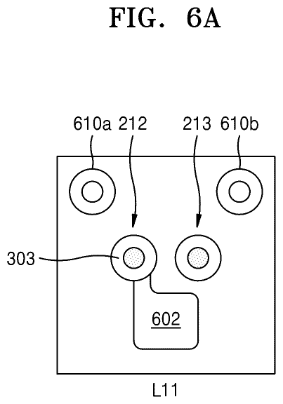

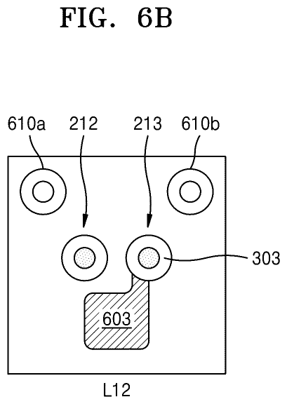

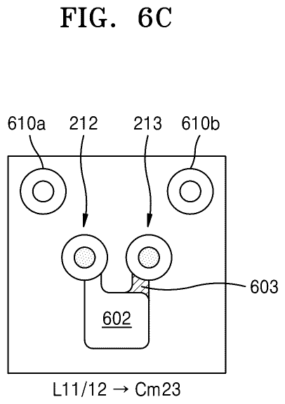

As a non-limiting example for description purposes only, the via structures 212 and 213 are formed in the lower layers 202 of the PCB 110, the signal entry point 302 is formed in the ninth layer L9, and the signal exit point 304 is formed in the sixteenth layer L16. The mutual capacitance point 330 of the via structure 212 is formed on the eleventh layer L11 and may be correlated with a plate formed on the eleventh layer L11 (see, e.g., FIG. 6A). The mutual capacitance point 330 of the via structure 213 is formed on the twelfth layer L12 and may be correlated with a plate formed on the twelfth layer L12 (see, e.g., FIG. 6B). The plate of the eleventh layer L11 and the plate of the twelfth layer L12 may have an overlapping region with each other (see, e.g., FIG. 6C), and a capacitive coupling may be generated between the plates overlapping each other so as to increase a mutual capacitance. For example, a capacitance may be proportional to an overall surface area of overlapping plates.

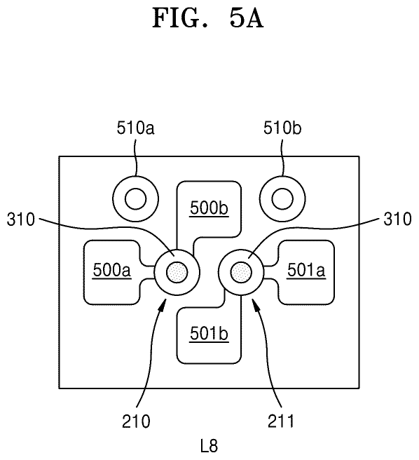

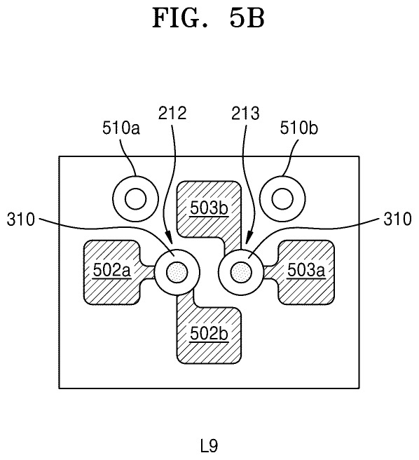

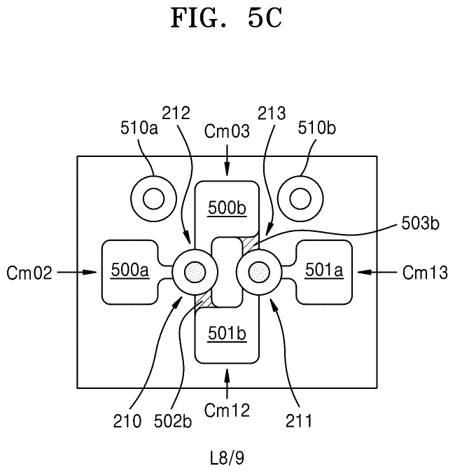

The via structures 210 and 212 may be disposed to overlap or at least partially overlap each other in a Z-axis direction. The conductive material film 310 of the eighth layer L8 where the signal exit point 304 of the via structure 210 is formed may be connected to a plate formed on the eighth layer L8 (e.g., FIG. 5A). The conductive material film 310 of the ninth layer L9 where the signal entry point 302 of the via structure 212 is formed may be connected to a plate formed in the ninth layer L9 (e.g., FIG. 5B). The plate of the eighth layer L8 and the plate of the ninth layer L9 may have overlapping regions (e.g., FIG. 5C), and a capacitive coupling may be generated between the plates overlapping each other so as to increase a mutual capacitance, e.g., based on an area of overlap between the respective plates.

The via structures 211 and 213 may also be disposed to overlap with each other in the Z-axis direction. The conductive material film 310 of the eighth layer L8 where the signal exit point 304 of the via structure 211 is formed may be connected to a plate formed on the eighth layer L8 (see, e.g., FIG. 5A). The conductive material film 310 of the ninth layer L9 where the signal entry point 302 of the via structure 212 is formed may be connected to a plate formed in the ninth layer L9 (see, e.g., FIG. 5B). The plate of the eighth layer L8 and the plate of the ninth layer L9 may have overlapping regions (e.g., FIG. 5C), and a capacitive coupling may be generated between the plates overlapping each other so as to increase a mutual capacitance.

FIGS. 4A to 6C are diagrams illustrating capacitance patterns included in via structures according to some example embodiments. FIGS. 4A to 4C are diagrams illustrating capacitance patterns of the fifth layer L5 and the sixth layer L6 of the PCB 110 of FIG. 2. FIGS. 5A to 5C are diagrams illustrating capacitance patterns of the eighth layer L8 and the ninth layer L9 of the PCB 110 of FIG. 2. FIGS. 6A to 6C are diagrams illustrating capacitance patterns of the eleventh layer L11 and the twelfth layer L12 of the PCB 110 of FIG. 2.

Referring to FIG. 4A in connection with FIGS. 2 to 3C, the via structures 210 and 211 are adjacently disposed on the fifth layer L5 of the PCB 110, ground vias 410a and 410b are disposed around the via structures 210 and 211, and the conductive material film 310 of the via structure 210 is connected to a metal plate 400. The ground vias 410a and 410b may include a barrel filled with a conductive material film and may be connected to a ground voltage line of the PCB 110; example embodiments, however, are not limited thereto. In FIG. 4B, the via structures 210 and 211 are adjacently disposed on the sixth layer L6 of the PCB 110, ground vias 410a and 410b are disposed around the via structures 210 and 211, and the conductive material film 310 of the via structure 211 is connected to a metal plate 401. In FIG. 4C, mutual capacitance Cm01 due to capacitive coupling may be generated at a portion where the metal plate 400 of the fifth layer L5 and the metal plate 401 of the sixth layer L6 overlap each other. Accordingly, the fifth layer L5 on which the metal plate 400 is formed may provide the mutual capacitance point 330 of the via structure 210, and the sixth layer L6 on which the metal plate 401 is formed may provide the mutual capacitance point 330 of the via structure 211.

Referring to FIGS. 4A-4C, there may be an insulating material such as but not limited to plastic and/or ceramic that surrounds the metal plates 400 and 401 at each layer at the fifth layer L5 and the sixth layer L6, respectively. Referring to FIG. 4C, there may be a thin layer, such as a thin dielectric layer, between the metal plate 400 and the metal plate 401, e.g., between the fifth layer L5 and the sixth layer L6, and the metal plate 400 and the metal plate 401 may not be in direct contact with each other; example embodiments are not limited thereto.

Referring to FIG. 5A in connection with FIGS. 2 to 3C, the via structures 210 and 211 are adjacently disposed on the eighth layer L8 of the PCB 110, ground vias 510a and 510b are disposed around the via structures 210 and 211, the conductive material film 310 of the via structure 210 is connected to metal plates 500a and 500b, and the conductive material film 310 of the via structure 211 is connected to metal plates 501a and 501b. In FIG. 5B, the via structures 212 and 213 are adjacently disposed on the ninth layer L9 of the PCB 110, ground vias 510a and 510b are disposed around the via structures 212 and 213, the conductive material film 310 of the via structure 212 is connected to metal plates 502a and 502b, and the conductive material film 310 of the via structure 213 is connected to metal plates 503a and 503b.

A size and/or a shape of each of the metal plates 500a, 500b, 501a, and 501b may be the same as each other; alternatively, at least one of a size and/or a shape of at least one of the metal plates 500a, 500b, 501a, and 501b may be different from others of the metal plates 500a, 500b, 501a, and 501b. In some example embodiments, one or more of the metal plates 500a, 500b, 501a, and 501b may have a rectangular shape or a beveled rectangular shape, such as a square shape or a beveled square shape; however, example embodiments are not limited thereto.

In FIG. 5C, mutual capacitances according to capacitive coupling may be generated at portions where the metal plates 500a, 500b, 501a, and 501b of the eighth layer L8 and the metal plates 502a, 502b, 503a, and 503b of the ninth layer L9 overlap each other. As an example, mutual capacitance Cm02 due to capacitive coupling may be generated at a portion where the metal plate 500a of the eighth layer L8 and the metal plate 502a of the ninth layer L9 overlap each other, mutual capacitance Cm03 due to capacitive coupling may be generated at a portion where the metal plate 500b of the layer L8 and the metal plate 503b of the ninth layer L9 overlap each other, mutual capacitance Cml3 due to capacitive coupling may be generated at a portion where the metal plate 501a of the eighth layer L8 and the metal plate 503a of the ninth layer L9 overlap each other, and mutual capacitance Cm12 due to capacitive coupling may be generated at a portion where the metal plate 501b of the eighth layer L8 and the metal plate 502b of the ninth layer L9 overlap each other.

Referring to FIG. 6A in connection with FIGS. 2 to 3C, the via structures 212 and 213 are adjacently disposed on the eleventh layer L11 of the PCB 110, and ground vias 610a and 610b are disposed around the via structures 212 and 213, and the conductive material film 303 of the via structure 212 is connected to a metal plate 602. In FIG. 6B, the via structures 212 and 213 are disposed adjacent to each other on the twelfth layer L12 of the PCB 110, ground vias 610a and 610b are disposed around the via structures 212 and 213, and the conductive material film 303 of the via structure 213 is connected to a metal plate 603. In FIG. 6C, mutual capacitance Cm23 due to capacitive coupling may be generated at a portion where the metal plate 602 of the 11th layer L11 and the metal plate 603 of the twelfth layer L12 overlap with each other. Accordingly, the 11th layer L11 on which the metal plate 602 is formed may provide the mutual capacitance point 330 of the via structure 212, and the twelfth layer L12 on which the metal plate 603 is formed may provide the mutual capacitance point 330 of the via structure 213.

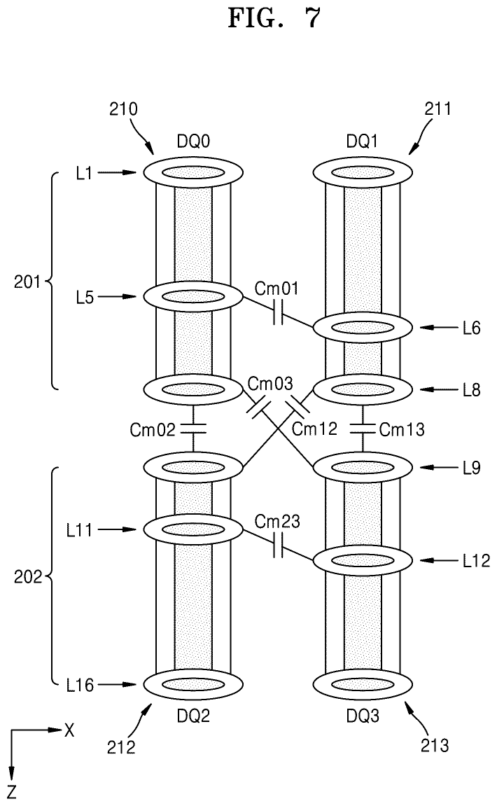

FIG. 7 is a diagram illustrating mutual capacitances of via structures according to various example embodiments. FIG. 7 shows mutual capacitances between the via structures 210, 211, 212, 213, and 220 of the PCB 110 of FIG. 2. The particular arrangements of the via structures 210, 211, 212, 213, and 220 of the PCB 110 are not limited thereto, and FIG. 7 is illustrative only.

Referring to FIG. 7 in connection with FIGS. 2 to 6C, the via structures 210 and 211 may be disposed adjacent to each other in the X-axis direction on the upper layers 201 of the PCB 110, and the via structures 212 and 213 may be disposed adjacent to each other in the X-axis direction on the upper layers 201 of the PCB 110. The via structures 210 and 212 may overlap in the Z-axis direction, and the via structures 211 and 213 may overlap in the Z-axis direction.

A coupling capacitor having a mutual capacitance Cm01 may exist between the via structures 210 and 211 at a portion where the metal plate 400 of the fifth layer L5 and the metal plate 401 of the sixth layer L6 of the PCB 110 overlap each other. A coupling capacitor having a mutual capacitance Cm23 may exist between the via structures 212 and 213 at a portion where the metal plate 602 of the eleventh layer L11 and the metal plate 603 of the twelfth layer L12 of the PCB 110 overlap each other. A coupling capacitor having a mutual capacitance Cm02 may exist between the via structures 210 and 212 at a portion where the metal plate 500a of the eighth layer L8 and the metal plate 502a of the ninth layer L9 of the PCB 110 overlap each other. A coupling capacitor having a mutual capacitance Cml3 may exist between the via structures 211 and 213 at a portion where the metal plate 501a of the eighth layer L8 and the metal plate 503a of the ninth layer L9 of the PCB 110 overlap each other. A coupling capacitor having a mutual capacitance Cm03 may exist between the via structures 210 and 213 at a portion where the metal plate 500b of the eighth layer L8 and the metal plate 503b of the ninth layer L9 of the PCB 110 overlap each other. A coupling capacitor having a mutual capacitance Cm12 may exist between the via structures 211 and 212 at a portion where the metal plate 501b of the eighth layer L8 and the metal plate 502b of the ninth layer L9 of the PCB 110 overlap each other.

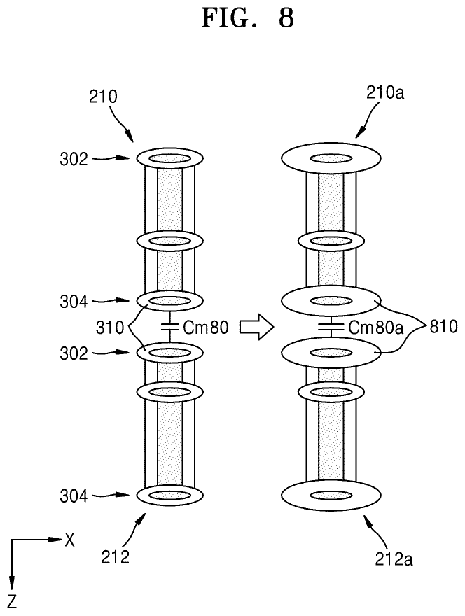

FIG. 8 is a diagram illustrating a via structure according to some example embodiments. Hereinafter, suffixes (e.g., a of 210a and a of 212a) attached to the same reference numeral in different drawings are for distinguishing a plurality of circuits having similar or identical functions.

Referring to FIG. 8, a coupling capacitor having a mutual capacitance Cm80 may exist at portions where the conductive material films 310 of via land regions of the signal exit point 304 of the via structure 210 and the signal entry point 302 of the via structure 212 overlap each other. In order to increase the mutual capacitance Cm80, relatively wide conductive material films 810 may be formed in the via land regions of the signal exit point 304 and the signal entry point 302 as in the via structures 210a and 212a. In the via structures 210a and 212a overlapping in the Z-axis direction, a mutual capacitance Cm80a generated at portions where the conductive material films 810 of the via land regions of the signal exit point 304 and the signal entry point 302 overlap each other may increase to be greater than the mutual capacitance Cm80 of the via structures 210 and 212.

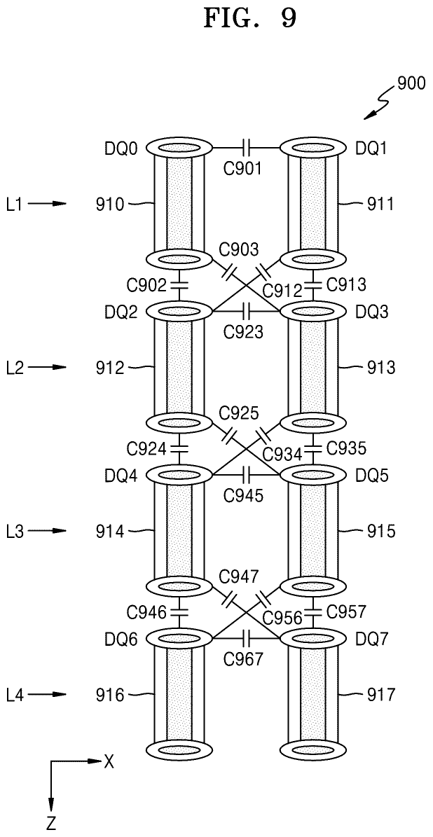

FIG. 9 is a diagram illustrating a via structure according to some example embodiments. For brevity of the drawing, FIG. 9 illustrates via structures 910 to 917 included in first to fourth layers L1 to L4 among the first to sixteenth layers L1 to L16 of the multilayer PCB 110 described with reference to FIG. 2, but actually, the via structures 910 to 917 may also be included in the first to sixteenth layers L1 to L16.

Referring to FIG. 9, the via structures 910 to 917 are signal vias and may be disposed in each of the first to fourth layers L1 to L4. As an example, the via structures 910 and 911 respectively connected to each of the DQ0 and DQ1 data signals are disposed on the first layer L1, the via structures 912 and 913 respectively connected to each of the DQ2 and DQ3 data signals are disposed on the second layer L2, the via structures 914 and 915 respectively connected to each of the DQ4 and DQ5 data signals are disposed on the third layer L3, and the via structures 916 and 917 respectively connected to each of the DQ6 and DQ7 data signals are disposed on the fourth layer L4.

The via structures 910 to 917 may include a laser via hole (LVH) barrel. The LVH barrel formed on each of the first to fourth layers L1 to L4 may include an insulating layer, and may be formed through processes including attaching a first metal layer and a second metal layer to upper and lower surfaces of the insulating layer by applying a particular (such as a dynamically determined or predetermined) heat and/or a particular (such as a dynamically determined or a predetermined) pressure, etching the first metal layer where a via hole is to be formed, forming the via hole using a laser device, and forming a plating layer by plating an inside of the via hole. The plating layer formed on the LVH may be electrically connected to the first metal layer and the second metal layer. The first metal layer and the second metal layer connected to the LVH plating layer in the via structures 910 to 917 may function as metal plates. The first metal layer and the second metal layer overlapping each other in the adjacent via structures 910 to 917 may exist as coupling capacitors having mutual capacitance.

For example, a coupling capacitor having a mutual capacitance C901 may exist between the via structures 910 and 911, a coupling capacitor having a mutual capacitance C902 may exist between the via structures 910 and 912, and a coupling capacitor having a mutual capacitance C903 may exist between the via structures 910 and 913. A coupling capacitor having a mutual capacitance C912 may exist between the via structures 911 and 912, and a coupling capacitor having a mutual capacitance C913 may exist between the via structures 911 and 913. A coupling capacitor having a mutual capacitance C923 may exist between the via structures 912 and 913, a coupling capacitor having a mutual capacitance C924 may exist between the via structures 912 and 914, and a coupling capacitor having a mutual capacitance C925 may exist between the via structures 912 and 915. A coupling capacitor having a mutual capacitance C934 may exist between the via structures 913 and 914, and a coupling capacitor having a mutual capacitance C935 may exist between the via structures 913 and 915. A coupling capacitor having a mutual capacitance C945 may exist between the via structures 914 and 915, a coupling capacitor having a mutual capacitance C946 may exist between the via structures 914 and 916, and a coupling capacitor having a mutual capacitance C947 may exist between 914 and 917. A coupling capacitor having a mutual capacitance C956 may exist between the via structures 915 and 916, and a coupling capacitor having a mutual capacitance C957 may exist between the via structures 915 and 917. A coupling capacitor having a mutual capacitance C967 may exist between the via structures 916 and 917. A capacitance of each of the coupling capacitors may be determined based on, e.g., may be proportional to, an amount of overlap of respective metal plates.

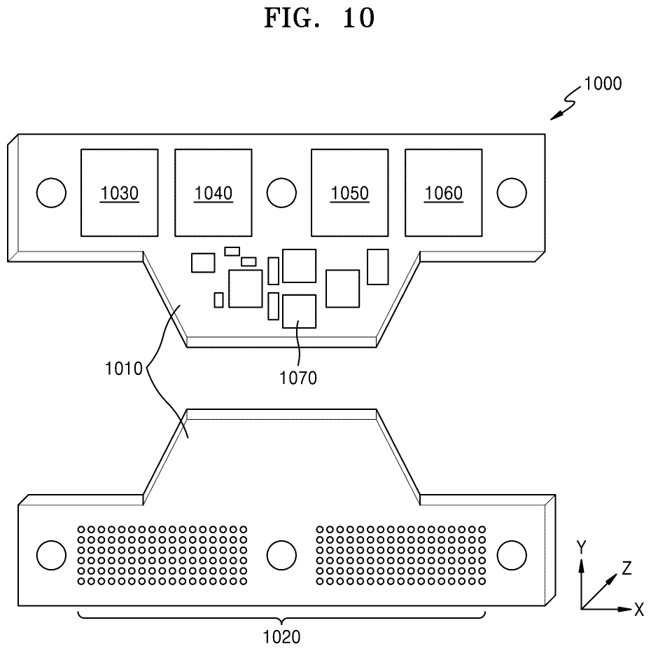

FIGS. 10 to 12 are diagrams illustrating memory modules according to some example embodiments.

Referring to FIG. 10, a memory module 1000 may include a module substrate 1010, a module connector 1020, memory packages 1030, 1040, 1050, and 1060, and passive elements 1070. The memory packages 1030, 1040, 1050, and 1060 may include LPDDR DRAMs, and the memory module 1000 may include a low power compression-attached memory module (LP-CAMM). The module substrate 1010 may include a multi-layer PCB 1010, a plurality of memory packages 1021 to 1029 may be mounted on an upper surface of the multi-layer PCB 1010, and a module connector 1020 may be disposed at a position opposite pins of the memory packages 1021 to 1029 on a real surface of the PCB 1010.

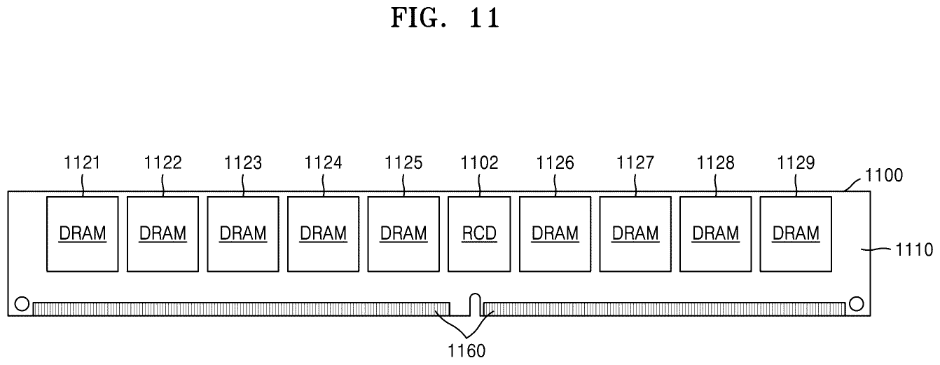

Referring to FIG. 11, a memory module 1100 may include a plurality of memory chips 1121 to 1129 mounted on an upper surface of a multi-layer PCB 1110 and a connector 1160 having a tab pin type. The memory module 1100 may include a registered DIMM (RDIMM); however, example embodiments are not limited thereto. A plurality of memory chips may also be disposed on the lower surface of the multi-layer PCB 1110. Although nine memory chips are illustrated, example embodiments are not limited thereto. A register 1102 may have a function of buffering and re-driving command, address, and control signals received through the connector 1160. Command, address, and control signals output from the register 1102 may be provided to the memory chips 1121 to 1129. For example, the register 1102 may provide one or more of command, address, and control signals to all memory chips 1121 to 1129 through common signal wires, through individual signal wires for each memory chip 1121 to 1129, or through each of signal wires to each of some of several memory chips 1121 to 1129. The number of memory chips 1121 to 1129 may be determined according to the structure and I/O configuration of the memory module 1100.

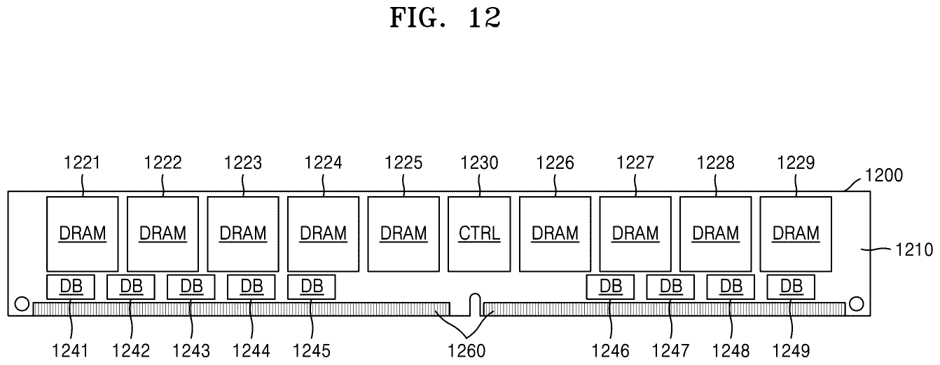

Referring to FIG. 12, a memory module 1200 may include a plurality of memory chips 1221 to 1229, a controller 1230, data buffers 1241 to 1249, and a connector 1260 having a tap pin type. The memory module 1200 may include a load reduced dual in-line memory module (LRDIMM). The memory chips 1221 to 1229, the controller 1230, and the data buffers 1241 to 1249 may be implemented in different semiconductor packages from each other and may be disposed on one side or both sides of a multi-layer PCB 1210, respectively. The controller 1230 may convert command, address, and control signals received through the connector 1260 into internal command, internal address, and internal control signals and transmit the converted internal command, internal address, and internal control signals to the memory chips 1221 to 1229. The controller 1230 may control the memory chips 1221 to 1229 using internal commands, internal addresses, and internal control signals. The controller 1230 may transmit a buffer command to the data buffers 1241 to 1249 and control the data buffers 1241 to 1249 using the buffer command. The memory chips 1221 to 1229 are respectively connected to the data buffers 1241 to 1249 and may exchange internal data signals and internal clock signals with the data buffers 1241 to 1249. The data buffers 1241 to 1249 may exchange external data signals and external clock signals with an external memory controller outside the memory module 1200 through the connector 1260.

The PCBs 1010, 1110, and 1210 of FIGS. 10 to 12 may include a first via structure that partially penetrates the multi-layers of the PCB 1010, 1110, and 1210 and is connected to a first metal plate disposed on a first layer among the multi-layers and a second via structure disposed adjacent to the first via structure in a horizontal direction, partially penetrating the multi-layers of the PCB, and connected to a second metal plate disposed on a second layer of the multi-layers. A portion where the first metal plate and the second metal plate overlap each other may provide a first mutual capacitive coupling between the first and second via structures. The PCBs 1010, 1110, and 1210 may include N layers sequentially stacked, and may include N via structures respectively transmitting N signals and penetrating each of the N layers of the PCB. The first mutual capacitive coupling may be provided between first and second via structures adjacent to each other in a horizontal direction of the PCB among the N via structures, and a second mutual capacitive coupling may be provided between third and fourth via structures overlapping each other in a vertical direction with each of the first and second via structures. The via structures may include a conductive material film including an insulating material layer at the center of a barrel formed on the PCBs 1010, 1110, and 1210. The barrel partially penetrates the multi-layers of the PCBs 1010, 1110, and 1210 to provide a signal entry point and a signal exit point, and among the layers that penetrate between the signal entry point and the signal exit point, the layers on which the metal plate is formed may provide a mutual capacitance point. The conductive material layer in the region of the signal entry point and signal exit point may be greater than the conductive material layer in the region of the mutual capacitance point.

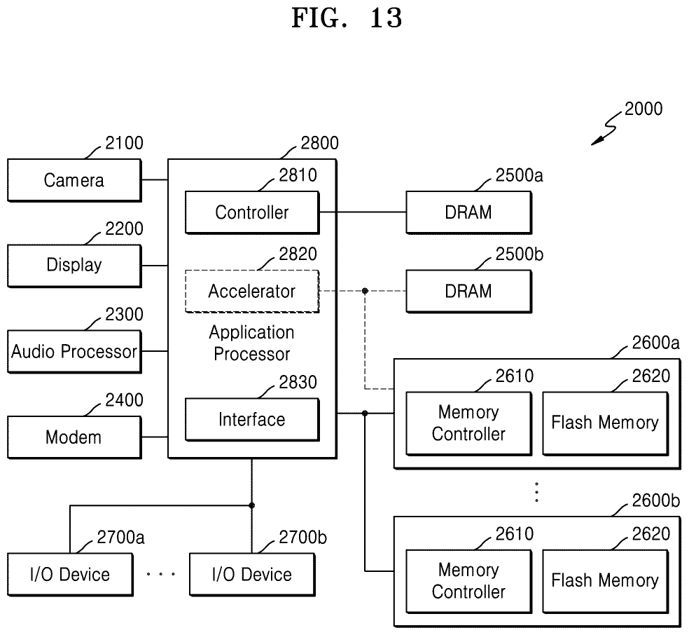

FIG. 13 is a block diagram of a system 2000 for describing an electronic apparatus including a memory module according to some example embodiments.

Referring to FIG. 13, the system 2000 may include a camera 2100, a display 2200, an audio processing unit 2300, a modem 2400, DRAMs 2500a and 2500b, flash memories 2600a and 2600b, I/O devices 2700a and 2700b, and an application processor 2800 (hereinafter referred to as “AP”). The system 2000 is implemented as or include or be included in one or more of a laptop computer, a mobile phone, a smart phone, a tablet personal computer (tablet PC), a wearable device, a healthcare device, or an Internet of Things (IoT) device. Also, the system 2000 may be implemented as or include or be included in a server and/or a personal computer.

The camera 2100 may capture a still image or a moving image under user control and may store and/or transmit the captured image/video data to the display 2200. The audio processing unit 2300 may process audio data included in the flash memories 2600a and 2600b or contents of the network. The modem 2400 modulates and/or transmits a signal for transmission/reception of wired/wireless data and may demodulate to restore an original signal at the receiving side. The I/O devices 2700a and 2700b may include devices that provide digital inputs and/or output function such as one or more of a universal serial bus (USB), a storage, digital cameras, secure digital (SD) cards, digital versatile discs (DVDs), network adapters, touch screens, etc.

The AP 2800 may control overall operations of the system 2000. The AP 2800 may include a control block 2810, an accelerator block or accelerator chip 2820, and an interface block 2830. The AP 2800 may control the display 2200 to display some of the contents stored in the flash memories 2600a and 2600b on the display 2200. When a user input is received through the I/O devices 2700a and 2700b, the AP 2800 may perform a control operation corresponding to the user input. The AP 2800 may include an accelerator block, which is a dedicated circuit for artificial intelligence (AI) data calculation, or may include an accelerator chip 2820 separate from the AP 2800. Inn some example embodiments, a DRAM 2500b may be additionally mounted on the accelerator block or the accelerator chip 2820. An accelerator is a functional block that specializes in performing specific functions of the AP 2800 and may include one or more of a GPU which is a functional block that specializes in graphic data processing, a neural processing unit (NPU) which is a block that specializes in AI calculation and inference, and a data processing unit (DPU) which is a block that specializes in data transmission.

The system 2000 may include a plurality of DRAMs 2500a and 2500b. The AP 2800 may control the DRAMs 2500a and 2500b through command and mode register (MRS) settings conforming to the (Joint Electron Device Engineering Council (JEDEC) standard, or to use company-specific functions such as low voltage/high speed/reliability and cyclic redundancy check (CRC)/error correction code (ECC) functions, DRAM interface rules may be set and communicated. For example, the AP 2800 may communicate with the DRAM 2500a through an interface conforming to the JEDEC standard such as LPDDR4 and/or LPDDR5, and the accelerator block or accelerator chip 2820 may communicate by setting a new DRAM interface protocol to control the accelerator DRAM 2500b having a higher bandwidth than the DRAM 2500a.

Although only the DRAMs 2500a and 2500b are shown in FIG. 13, but it is not limited thereto, and if one or more of a bandwidth, response speed, and voltage conditions of the AP 2800 or the accelerator chip 2820 are satisfied, any memory, such as one or more of a memory of PRAM, SRAM, MRAM, RRAM, FRAM, or Hybrid RAM may be used. The DRAMs 2500a and 2500b have relatively less latency and bandwidth than the I/O devices 2700a and 2700b or the flash memories 2600a and 2600b. The DRAMs 2500a and 2500b are initialized when the system 2000 is powered on and when an operating system and application data are loaded, the DRAMs 2500a and 2500b may be used as temporary storages for the operating system and application data or as execution spaces for various software codes.

In the DRAMs 2500a and 2500b, one or more of the four arithmetic operations of addition/subtraction/multiplication/division and vector operations, address operations, or Fast Fourier Transform (FFT) operations may be performed. In addition, in the DRAMs 2500a and 2500b, a function for execution used for inference may be performed. Here, the inference may be performed in a deep learning algorithm using an artificial neural network. The deep learning algorithm may include a training operation of learning a model through various data and an inference operation of recognizing data with the learned model. In some example embodiments, an image captured by a user through the camera 2100 is signal-processed and stored in the DRAM 2500b, and the accelerator block or the accelerator chip 2820 may perform an AI data operation that recognizes data using the data stored in the DRAM 2500b and a function used for inference.

The system 2000 may include a plurality of storages or a plurality of flash memories 2600a and 2600b having a greater capacity than the DRAMs 2500a and 2500b. The accelerator block or accelerator chip 2820 may perform a training operation and an AI data operation using the flash memories 2600a and 2600b. In one embodiment, the flash memories 2600a and 2600b may include a memory controller 2610 and a flash memory device 2620 and may perform a training operation and an inference AI data operation performed by the AP 2800 and/or the accelerator chip 2820 more efficiently using an arithmetic unit included in the memory controller 2610. The flash memories 2600a and 2600b may store photos taken through the camera 2100 or data transmitted through a data network. For example, the flash memories 2600a and 2600b may store augmented reality/virtual reality, high definition (HD), or ultra-high definition (UHD) contents.

In the system 2000, the DRAMs 2500a and 2500b and/or the flash memories 2600a and 2600b may include the memory module described with reference to FIGS. 1 to 12. The memory module includes a multi-layer PCB, a first via structure that partially penetrates the multi-layers of the PCB and is connected to a first metal plate disposed in a first layer among the multi-layers, and a second via structure disposed adjacent to the first via structure in a horizontal direction, partially penetrating the multi-layers of the PCB, and connected to a second metal plate disposed on a second layer of the multi-layers. A portion where the first metal plate and the second metal plate overlap each other may provide a first mutual capacitive coupling between the first and second via structures. The memory module may include a PCB including sequentially stacked N layers and N via structures respectively transmitting N signals and penetrating each of the N layers of the PCB. Among the N via structures, a first mutual capacitive coupling may be provided between first and second via structures adjacent to each other in the horizontal direction of the PCB and a second mutual capacitive coupling may be provided between the third and fourth via structures overlapping each of the first and second via structures in the vertical direction. The via structures may include a conductive material film having an insulating material film embedded in the central portion of a barrel formed on a multi-layer PCB. The barrel may provide a signal entry point and a signal exit point by partially penetrating the multi-layers of the PCB, and among the layers penetrated between the signal entry and exit points, a layer on which a metal plate is formed may provide a mutual capacitance point. The conductive material film in a region of the signal entry and exit points may be greater than the conductive material film in a region of the mutual capacitance point. The memory module may provide a high-speed and high-performance solution of a memory device by effectively reducing crosstalk and removing signaling interference and noise using via structures forming mutual capacitive coupling.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various inventive concepts have been particularly shown and described with reference to some example embodiments thereof, it will be understood that various changes in form and details may be made therein without departing from the spirit and scope of the following claims. Furthermore example embodiments are not necessarily mutually exclusive with one another. For example, some example embodiments may include one or more features described with reference to one or more figures, and may also include one or more other features described with reference to one or more other figures.

What is claimed is:

1. An apparatus comprising:
a printed circuit board (PCB) including sequentially stacked multi-layers;
a first via structure that partially penetrates the multi-layers of the PCB and is connected to a first metal plate that is on a first layer of the multi-layers; and
a second via structure adjacent to the first via structure in a horizontal direction, partially penetrating the multi-layers of the PCB, and connected to a second metal plate that is on a second layer of the multi-layers,
wherein a portion where the first metal plate and the second metal plate overlap each other are configured to provide a first mutual capacitive coupling between the first and second via structures.

2. The apparatus of claim 1, wherein the first layer and the second layer are adjacent to each other in a vertical direction of the PCB.

3. The apparatus of claim 1, further comprising:
a third via structure adjacent to the first via structure in a vertical direction,
wherein a portion where the first and third via structures overlap in the vertical direction is configured to provide a second mutual capacitive coupling.

4. The apparatus of claim 3, wherein a third mutual capacitive coupling extending from the second via structure toward the third via structure is configured to be provided between the second and third via structures.

5. The apparatus of claim 3, further comprising:
a fourth via structure adjacent to the second via structure in the vertical direction,
wherein a portion where the second and fourth via structures overlap in the vertical direction are configured to provide a fourth mutual capacitive coupling.

6. The apparatus of claim 5, wherein a fifth mutual capacitive coupling extending from the first via structure toward the fourth via structure is configured to be provided between the first and fourth via structures.

7. The apparatus of claim 1, wherein the first and second via structures each independently include at least one of blind via hole barrel or a buried via hole barrel that partially penetrate the multi-layers.

8. The apparatus of claim 1, further comprising: g
round via structures arranged around the first and second via structures.

9. The apparatus of claim 1, wherein the apparatus includes a memory module of at least one of a compression-attached memory module (CAMM), a low power compression-attached memory module (LP-CAMM), a registered DIMM (RDIMM), and a load reduced dual in-line memory module (LRDIMM).

10. An apparatus comprising:
a printed circuit board (PCB) including sequentially stacked N (N is a natural number) layers; and
N via structures respectively configured to transmit N signals and passing through each of the N layers of the PCB,
wherein a first mutual capacitive coupling is configured to be provided between first and second via structures adjacent to each other in a horizontal direction of the PCB among the N via structures, and
a second mutual capacitive coupling is configured to be provided between third and fourth via structures overlapping each of the first and second via structures in a vertical direction among the N via structures.

11. The apparatus of claim 10, wherein a third mutual capacitive coupling extending from the first via structure toward the third via structure is configured to be provided between the first and third via structures.

12. The apparatus of claim 10, wherein a third mutual capacitive coupling extending from the first via structure toward the fourth via structure is configured to be provided between the first and fourth via structures;

13. The apparatus of claim 10, wherein a third mutual capacitive coupling extending from the second via structure toward the third via structure is configured to be provided between the second and third via structures;

14. The apparatus of claim 10, wherein a third mutual capacitive coupling extending from the second via structure toward the fourth via structure is configured to be provided between the second and fourth via structures.

15. The apparatus of claim 10, further comprising:
a first metal plate connected to the first via structure in a layer on which the first via structure is arranged from among the N layers; and
a second metal plate connected to the third via structure in a layer on which the third via structure is arranged from the N layers,
wherein a portion where the first metal plate and the second metal plate overlap each other is configured to provide a third mutual capacitive coupling between the first and third via structures.

16. The apparatus of claim 10, wherein the N via structures each include a laser via hole (LVH) barrel passing through each of the N layers.

17. The apparatus of claim 10, wherein the apparatus is a memory module included in any one of a compression-attached memory module (CAMM), a low power compression-attached memory module (LP-CAMM), a registered DIMM (RDIMM), and a load reduced dual in-line memory module (LRDIMM).

18. A via structure comprising:
a barrel on a printed circuit board (PCB) that includes sequentially stacked multi-layers; and
a conductive material film having an insulating material film embedded in a center of the barrel,
wherein the barrel is configured to provide a signal entry point and a signal exit point by partially penetrating the multi-layers, and a layer on which a metal plate is arranged from among the penetrated layers between the signal entry point and the signal exit point is configured to provide a mutual capacitance point, and
the conductive material film in a region of the signal entry and exit points is arranged to be greater in size than the conductive material film in a region of the mutual capacitance point.

19. The via structure of claim 18, wherein the barrel includes at least one of a blind via hole barrel or a buried via hole barrel.

20. The via structure of claim 18, wherein the barrel includes a laser via hole barrel.
